(19) United States
(12) Patent Application Publication
(10) Pub. No.: US 2024/0266990 A1
(43) Pub. Date: Aug. 8, 2024

(54) Flexible Solar Panels Incorporated Within Non-Planar Generally-Rigid Vehicular Components

(71) Applicant: SOLARPAINT LTD., YOKNEAM ILLIT (IL)

(72) Inventors: Ramon Joseph Albalak, Haifa (IL); Yaron Tidhar, Even Yehuda (IL)

(21) Appl. No.: 18/631,106

(22) Filed: Apr. 10, 2024

Related U.S. Application Data
(63) Continuation of application No. PCT/IL2022/051146, filed on Oct. 30, 2022.
(63) Continuation-in-part of application No. 18/129,865, filed on Apr. 2, 2023.
Application No. 18/129,865 is a continuation of application No. PCT/IL2021/051202, filed on Oct. 7, 2021.
Application No. PCT/IL2021/051202 is a continuation-in-part of application No. 17/353,867, filed on Jun. 22, 2021, now Pat. No. 11,978,815.
Application No. 18/129,865 is a continuation-in-part of application No. 17/353,867, filed on Jun. 22, 2021, now Pat. No. 11,978,815.
Application No. 17/353,867 is a continuation-in-part of application No. 16/362,665, filed on Mar. 24, 2019, now Pat. No. 11,081,606.
Application No. 17/353,867 is a continuation-in-part of application No. PCT/IL2019/051416, filed on Dec. 26, 2019.
Application No. PCT/IL2019/051416 is a continuation-in-part of application No. 16/362,665, filed on Mar. 24, 2019, now Pat. No. 11,081,606.
Application No. 18/129,865 is a continuation-in-part of application No. 17/802,335, filed on Aug. 25, 2022.
(60) Provisional application No. 63/273,940, filed on Oct. 31, 2021.
(60) Provisional application No. 63/088,535, filed on Oct. 7, 2020.
(60) Provisional application No. 62/785,282, filed on Dec. 27, 2018.
(60) Provisional application No. 62/785,282, filed on Dec. 27, 2018.
(60) Provisional application No. 62/982,536, filed on Feb. 27, 2020.

(51) Int. Cl. H02S 20/30; B60L 8/00; H02S 30/10; H02S 40/38

(52) U.S. Cl. CPC H02S 20/30; B60L 8/003; H02S 30/10; H02S 40/38

(57) ABSTRACT

A vehicular component, such as vehicular roof or vehicular hood or vehicular door or vehicular side-panel or vehicular trunk cover, has a plurality of electrically interconnected flexible solar cells, that are integrally embedded therein. Optionally, the vehicular component has curvatures or has non-planar regions or curved regions; and the integrally embedded flexible solar cells are arranged in a three-dimensional structure that follows or matches the vehicular contour. The embedded flexible solar panels are not directly in touch with the air that surrounds the vehicle; rather, they are infused or embedded within one or more layers of the vehicular component; optionally sandwiched between encapsulant layers; optionally further sandwiched between a topsheet and a backsheet; optionally further sandwiched between two thermoformed layers that are formed of polycarbonate or other thermoformable materials.

### CROSS-REFERENCE TO RELATED APPLICATIONS

This patent application is a Continuation of PCT international application number PCT/IL2022/051146, having an international filing date of Oct. 30, 2022, which is hereby incorporated by reference in its entirety.

The above-mentioned PCT/IL2022/051146 claims priority and benefit from U.S. 63/273,940, filed on Oct. 31, 2021, which is hereby incorporated by reference in its entirety.

This patent application is also a Continuation-in-Part (CIP) of U.S. Ser. No. 18/129,865, filed on Apr. 2, 2023, which is hereby incorporated by reference in its entirety.

The above-mentioned U.S. Ser. No. 18/129,865 is a Continuation of PCT international patent application number PCT/IL2021/051202, having an international filing date of Oct. 7, 2021, which is hereby incorporated by reference in its entirety.

The above-mentioned PCT/IL2021/051202 claims priority and benefit: (i) from U.S. 63/088,535, filed on Oct. 7, 2020, which is hereby incorporated by reference in its entirety; and (ii) from U.S. Ser. No. 17/353,867, filed on Jun. 22, 2021, which is hereby incorporated by reference in its entirety.

The above-mentioned U.S. Ser. No. 18/129,865 is also a Continuation-in-Part (CIP) of U.S. Ser. No. 17/353,867, filed on Jun. 22, 2021, which is hereby incorporated by reference in its entirety.

The above-mentioned U.S. Ser. No. 17/353,867 is a Continuation-in-Part (CIP) of U.S. Ser. No. 16/362,665, filed on Mar. 24, 2019, now patent number U.S. Pat. No. 11,081,606 (issued on Aug. 3, 2021), which is hereby incorporated by reference in its entirety; which claims priority and benefit from U.S. 62/785,282, filed on Dec. 27, 2018, which is hereby incorporated by reference in its entirety.

The above-mentioned U.S. Ser. No. 17/353,867 is also a Continuation-in-Part (CIP) of PCT international application number PCT/IL2019/051416, having an international filing date of Dec. 26, 2019, which is hereby incorporated by reference in its entirety.

The above-mentioned PCT/IL2019/051416 claims priority and benefit: (i) from U.S. Ser. No. 16/362,665, filed on Mar. 24, 2019, now patent number U.S. Pat. No. 11,081,606 (issued on Aug. 3, 2021), which is hereby incorporated by reference in its entirety, and (ii) from U.S. 62/785,282, filed on Dec. 27, 2018, which is hereby incorporated by reference in its entirety.

The above-mentioned U.S. Ser. No. 18/129,865 is also a Continuation-in-Part (CIP) of U.S. Ser. No. 17/802,335, filed on Aug. 25, 2022, which is hereby incorporated by reference in its entirety; which is a National Stage of PCT international application number PCT/IL2021/050217, having an international filing date of Feb. 25, 2021, which is hereby incorporated by reference in its entirety; which claims priority and benefit from U.S. 62/982,536, filed on Feb. 27, 2020, which is hereby incorporated by reference in its entirety.

### FIELD

Some embodiments relate to the field of solar panels and photovoltaic (PV) devices.

### BACKGROUND

The photovoltaic (PV) effect is the creation of voltage and electric current in a material upon exposure to light. It is a physical and chemical phenomenon.

The PV effect has been used in order to generate electricity from sunlight. For example, PV solar panels absorb sunlight or light energy or photons, and generate electricity through the PV effect.

### SUMMARY

Some embodiments provide flexible solar panels that are incorporated (or integrally embedded) within or into curved or non-planar articles; and particularly, curved or non-planar rigid or semi-rigid or mostly-rigid or relatively-rigid articles (e.g., a vehicular component, a vehicular roof, a vehicular hood cover or trunk cover, a vehicular door or side-panel), or other curved or non-planar articles (or articles having one or more curvatures or curved regions or non-planar regions) that are firm or relatively-firm or semi-firm or mostly-firm; including articles, such as vehicular parts, which are generally firm and generally rigid yet may have some degree of flexing capability in response to mechanical pressures or forces. Some embodiments further provide methods and systems for producing such articles having flexible solar panels that are embedded or infused therein.

In accordance with some embodiments, a vehicular component (such as: vehicular roof, vehicular hood, vehicular door, vehicular side-panel, vehicular trunk cover) has a plurality of electrically-interconnected flexible solar cells, that are integrally embedded therein. Optionally, the vehicular component has curvatures or has non-planar regions or curved regions; and the integrally embedded flexible solar cells are arranged in a three-dimensional structure that follows or matches the vehicular contour. The embedded flexible solar panels are not directly in touch with the air that surrounds the vehicle; rather, they are infused or embedded within one or more layers of the vehicular component; optionally sandwiched between encapsulant layers; optionally further sandwiched between a topsheet and a backsheet; optionally further sandwiched between two thermoformed layers that are formed of polycarbonate or other thermoformable materials.

Some embodiments may provide other and/or additional benefits and/or advantages.

### BRIEF DESCRIPTION OF THE DRAWINGS

FIG. 1 is a schematic illustration of a cross-sectional view (or a side-view) of an intermediate article that is intended to be embedded within a vehicular component, in accordance with some demonstrative embodiments.

FIG. 2 is a schematic illustration of a cross-sectional view (or a side-view) of a vehicular component having embedded therein said intermediate article, in accordance with some demonstrative embodiments.

FIG. 3 is a schematic illustration of a cross-sectional view (or a side-view) of a vehicular component having embedded therein another type of intermediate article, in accordance with some demonstrative embodiments.

FIG. 4 is a schematic illustration of an arrangement of multiple, generally-flexible, solar cells that are embedded within a vehicular hood or hood-cover, in accordance with some demonstrative embodiments.

FIG. 5 is a schematic illustration of a top-view of a vehicle, having vehicular components with embedded generally-flexible solar cells, in accordance with some demonstrative embodiments.

FIG. 6 is a schematic illustration of a cross-section view of a vehicle, having vehicular components with embedded generally-flexible solar cells, in accordance with some demonstrative embodiments.

### DETAILED DESCRIPTION OF SOME DEMONSTRATIVE EMBODIMENTS

The Applicants have realized that some conventional solar panels are typically rigid, heavy, cumbersome, brittle and/or fragile units, that are typically installed on roofs or in other locations (e.g., a solar energy park, a solar energy farm, a solar power plant).

The Applicants have realized that it may be beneficial to incorporated or embed, or to otherwise integrally attach or mount or non-detachably attach, a solar panel or a solar module, and particularly a generally-flexible solar panel (e.g., that does not break and/or does not become significantly damaged or non-functional if bent or curved or flexed), into or onto a vehicle or a vehicular component or a vehicular part (e.g., a vehicular roof, a vehicular trunk, a vehicular door); and particularly a curved or non-planar vehicular component, or a vehicular component having one or more curvatures and/or non-planar regions.

The Applicants have realized that such solar panel, embedded or integrated in such vehicular component, may generate electricity from light via the photovoltaic effect, while such vehicle is in motion and/or is parking or non-moving; and such PV-generated electricity may be immediately utilized by the vehicle itself, or by electronic devices within the vehicle, and/or may be stored by one or more batteries or power cells of the vehicle for later storage.

Applicants have realized that such solar panel, embedded or integrated in such vehicular component, may provide PV-generated electricity to various types of vehicles; for example, an Electric Vehicle (EV), an all-electric vehicle (e.g., that lacks any unit that utilizes gas or gasoline or petrol or petroleum), a Battery Electric Vehicle (BEV), a Plug-in Hybrid Electric Vehicle (PHEV), a Hybrid Electric Vehicle (HEV), or the like.

The Applicants have realized that an EV or BEV or PHEV often has high electrical demands and/or requires large consumption of electric power; and that an additional source of electric power (e.g., in addition to charging of the vehicular battery at a dedicated charger, which requires that the vehicle would be static and not moving) may be beneficial; particularly in vehicles that lack any gas-based or petroleum-based engine or that lack an internal combustion engine, or in vehicles that have such internal-combustion engine which is not running at all times.

The Applicants have realized that it may be beneficial to integrally incorporate flexible solar cells or flexible solar panels within firm or generally-firm or relatively-firm objects having one or more curvatures or having one or more non-planar regions; and particularly, in vehicular parts or vehicular components.

The term “vehicle” as used herein may comprise, for example, a car, a sedan car, a sport utility vehicle (SUV), a truck, a bus, a van, a minivan, a motorcycle, a motorized bicycle, a Personal Transporter device (e.g., Segway PT), a train, a wagon of a train, a car of a train, a military vehicle (e.g., a tank, an armored fighting vehicle (AFV), a combat vehicle, or the like), a first responder or law enforcement vehicle (e.g., police car, ambulance, firetruck), a cargo vehicle, a trailer, a mini-trailer, a vehicle for transporting persons and/or animals and/or other cargo, an agricultural vehicle or mobile agricultural equipment (e.g., a tractor, a combine harvester, a cotton harvester, a harvester, a crop sprayer, a hay baler, or the like), a vehicle having a generally flat roof, a vehicle having a curved roof, an autonomous car or vehicle, a self-driving car or vehicle, a remote-controlled car or vehicle, a remotely-controlled car or vehicle, or the like.

For demonstrative purposes, some portions of the discussion herein relate to a vehicle or to vehicular parts; however, these are only non-limiting examples, and some embodiments of the present invention may similarly be utilized in conjunction with other articles that are capable of moving and/or that consume electricity; for example, a ship, a boat, a yacht, a marine vessel, an airplane, a helicopter, an aircraft, a drone, a remotely-controlled drone, a self-operating drone, an Unmanned Aerial Vehicle (UAV), a self-driving vehicle, an autonomous-driving vehicle, a self-navigating or self-operating vessel or aircraft, a remotely-controlled vehicle or vessel or aircraft, a spaceship or spacecraft, or the like. Similarly, the term “vehicular”, as used herein, such as in the context of “vehicular component” or “vehicular part”, may include a similar adjective indicating being a part of such other article; such that a “marine vessel component” or an “aircraft component” may correspond to the “vehicular component” which is discussed as a non-limiting example.

Some embodiments provide a vehicular component having a transparent or translucent region or surface or layer or set-of-layers, which enables passage therethrough of at least 51 or 66 or 75 or 80 or 90 percent of light; such that the penetrating light reaches an integrated, internally embedded, solar panel or solar cell, that is non-detachably embedded within the vehicular component. In some embodiments, the internally-embedded solar panel is a generally-flexible solar panel; for example, formed by introducing trenches or grooves or non-transcending craters or non-transcending gaps or “blind gaps” that penetrate some—but not all—of the thickness (or the depth) of a silicon layer or a semiconductor body or a semiconductor wafer of the solar panel, and/or formed of a plurality or matrix or array of neighboring micro-cells or nano-cells that are mechanically and electrically inter-connected; and optionally by having filler material(s) in such grooves or trenches or non-transcending gaps or non-transcending craters, to further absorb and/or dissipate mechanical forces and shocks.

In some embodiments, the flexible solar cell or solar panel is embedded within a surface layer (or an outwardly-facing surface layer) of a vehicular component layer, which is “infused” with such embedded flexible solar panel. The flexible solar panel may thus be an integral part of a coating layer of an external surface or outwardly-facing surface or outwardly-facing layer of a vehicular component; for example, a vehicular roof, a vehicular door, a vehicular hood, a vehicular trunk, a vehicular “frunk” or front-side trunk, a vehicular side panel or top panel, a vehicular engine-cover, a vehicular metal frame, a vehicular chassis, or other structural component of a vehicle). Accordingly, the flexible solar cell is a thin, generally flexible, internal part or embedded part of such outer layer or outwardly-facing layer or outwardly-facing surface of the vehicular component.

In some embodiments, a plurality of such flexible internally-embedded solar panels may be electrically interconnected to each other, via a set or array of wires or metal conductors and particularly with flexible or semi-flexible metal conductors or wires. Each such flexible internally-embedded solar panel, or (in some embodiments) each set or group or batch of two or more neighboring flexible internally-embedded solar panels, is or are surrounded by (or sandwiched within, or encapsulated within) one or more vehicular surface-layer filler material(s), which surround and/or mechanically support and/or trap therein and/or hold therein (i) the internally-embedded flexible solar panel(s) and also (ii) the inter-connecting wires or metal conductors that collect and/or aggregate and/or transport the PV-generated electricity. Such vehicular surface-layer filler material(s) may include, for example, structurally durable plastic, polymer, silicon, glass, bio-fiber, synthetic fiber, a composition that includes two or more of these materials, and/or other suitable support materials or filler materials or encapsulation materials. The wires or metal conductors of the embedded solar cells or solar panels operate to collect and/or aggregate PV-generated electric current, and to transport it towards or into one or more sets of electrodes or electric terminals or power terminals of the vehicle, such that the PV-generated electricity may be stored in one or more vehicular batteries and/or may be consumed by electric parts of the vehicle. Accordingly, the flexible solar panel infused vehicular component, or the flexible solar panel infused vehicular outer surface, or the flexible solar panel infused vehicular outwardly-facing surface, may participate in electric energy production for the benefit of the vehicle (and/or for the benefit of electric devices or electronic devise that consume electricity from the vehicle through in-vehicle power outlets), when the vehicle is moving and/or when the vehicle is parking or non-moving.

In some embodiments, the thickness, the mechanical strength, the three-dimensional structure or shape, and/or other characteristics of the (at least partially) transparent or translucent vehicular surface layer (which has the flexible solar panel embedded therein) may be configured or selected during production based on the particular intended application of the layer. For example, the thickness and corresponding strength (or rigidity) of the layer that are intended for a vehicular structural element (e.g., a car roof) may be configured or selected to be relatively greater than those of a coating layer for such vehicular component Similarly, a vehicular component that is expected to undergo greater movement or slamming forces (e.g., car door), may have increased rigidity or strength or thickness than a generally-static vehicular component. Other parameters may be taken into account when configuring the thickness and/or rigidity level of such vehicular components that are “infused” with a flexible solar panel that is embedded therein.

In some embodiments, the desired thickness and/or three-dimensional structure of the (at least partially) transparent or translucent vehicle surface layer, which has the embedded flexible solar panel, may be configured or achieved during production using a mold or a set of multiple molds. For example, mold(s) can be used to thermoform a prefabricated sheet or bar of the solar cell infused material, having an application-specific thickness, into an application-specific shape or three-dimensional structure. In some embodiments, mold(s) for producing an application-specific shape or three-dimensional structure may be used to receive and hold, in an application-specific configuration, one or more solar panels or a mesh (or several meshes, or a matrix or array) of generally-flexible solar cells or generally-flexible solar panels, and to immerse a plurality of such generally-flexible solar panels in a monomer composition, and to cure or harden or solidify the composition into the application-specific shape or three-dimensional structure. Optionally, thermoforming molds and/or curing molds can be used to produce coating-layers and/or coating covers and/or structural elements (or portions of structural elements).

Some embodiments may specifically provide a solar-cell enabled vehicular roof cover (or vehicular hood cover, or vehicular trunk cover), by the incorporation or the embedding of generally-flexible and/or mechanically-resilient solar cells or solar panels into a thermoformed plastic vehicular roof; thereby enabling the production of a lightweight, aesthetic, efficient, and/or easy to install vehicular roof cover that precisely conforms to the three-dimensional contour of the vehicular roof itself.

In some embodiments, the use of flexible solar cell meshes allows for incorporation of a solar-cells layer into a curved or non-planar or non-flat product (e.g., which may have one or more curvatures or non-planar regions), which may be made by thermoforming or by other production methods. Some embodiments enable the manufacturing of a solar-cell-enabled or a solar-cell-embedded vehicular roof cover, that is significantly lighter than glass-based alternatives, and/or is cheaper or more cost-effective to produce when compared with glass-based alternatives, and/or is easier to install and/or repair and/or replace, and/or is aesthetic and durable; while also providing high efficiency of solar conversion and of PV-generation of electricity.

Some embodiments may include methods, systems, and materials for producing a rigid or semi-rigid or plastic-based solar car-roof covering or vehicular-roof covering, that incorporates therein a plurality of generally-flexible solar cells or solar panels. The embedded solar cells are electrically connected to each other in a configuration that produces electric voltage/electric current/electric power in accordance with target values to meet a particular electric profile or a particular electric consumption specification. In some embodiments, the internal embedding of generally-flexible solar cells or solar panels that are mechanically resilient, enables them to endure mechanical stresses that are encountered during the thermoforming process.

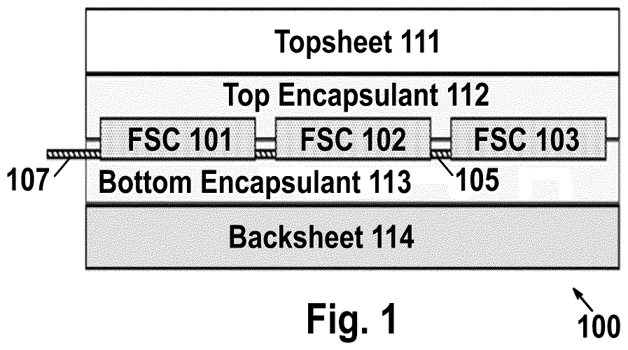

Reference is made to FIG. 1, which is a schematic illustration of a cross-sectional view (or a side-view) of an intermediate article 100 that is intended to be embedded within a vehicular component, in accordance with some demonstrative embodiments. There are shown a plurality of solar panels or solar cells, for example, Flexible Solar Cell (FSC) 101 and FSC 102 and FSC 103. Since this is a side-view or a cross-sectional view, the three FSC units (101 to 103) may represents columns or rows of similar FSC units, such that an array or matrix or mash of FSC units may be used in a single intermediate article 100.

Internal electrical contacts 105, such as metal wires or conductors, may connect or interconnect two (or more) neighboring FSC units (or rows of FSC units, or columns of FSC units); and may collect or aggregate or accumulate PV-generated electricity from a plurality of FSC units. External electrical contacts 107, such as metal wires or conductors, may transport the PV-generated electricity from the plurality of FSC units to a target recipient; for example, a vehicular battery that is recharged, or an electric-consuming component of the vehicle or other electricity-storing vehicular component or electricity-receiving vehicular component.

The intermediate article 100 is produced by encapsulating the electrically-connected mesh (or chain(s), or group(s), or array, or matrix) of FSC units within a multi-layer laminate that includes: a backsheet 114 and a topsheet 111, which sandwich or surround a bottom encapsulant 113 and a top encapsulant 112, which in turn sandwich or surround the plurality of interconnected FSC units 101-103. The encapsulants (112 and/or 113) may be or may include, for example, Ethylene-Vinyl Acetate (EVA) or poly(Ethylene-Vinyl Acetate) (PEVA), Polyolefin Elastomer (POE), or other suitable materials.

In some embodiments, backsheet 114 may be optional; and other embodiments may exclude any backsheet or any backsheet layer. In some embodiments, topsheet 111 may be optional; and other embodiments may exclude any topsheet or any topsheet layer. In some embodiments, the top encapsulant 112 may be optional; and other embodiments may exclude any such top encapsulant 112. In some embodiments, the bottom encapsulant 113 may be optional; and other embodiments may exclude any such bottom encapsulant 113. In some embodiments, a combination of two or more of the above features may be applied; such that, for example, the intermediate article may lack a backsheet and may also lack a top encapsulant. Other suitable combinations of layers may be used.

In some embodiments, the external electrical contacts 107 may be connected to the plurality of FSC units prior to their encapsulation or lamination or other “sandwiching” process. In other embodiments, the external electrical contacts 107 may be connected to the plurality of FSC units subsequent to their encapsulation or lamination or other “sandwiching” process.

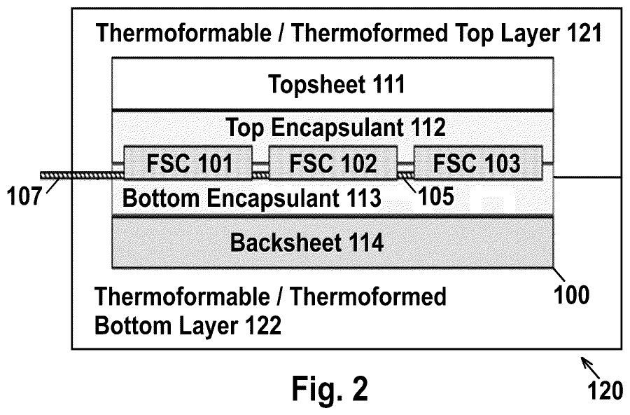

Reference is made to FIG. 2, which is a schematic illustration of a cross-sectional view (or a side-view) of a vehicular component 120 having embedded therein the intermediate article 100, in accordance with some demonstrative embodiments.

For example, once the intermediate article 100 was produced and is ready, it is introduced or embedded or incorporated or sandwiched between two layers of thermoformable plastic sheets; and a thermoforming process is performed a top layer 121 and a bottom layer 122 that together sandwich or contain the intermediate article 100 (which, in turn, encapsulates therein the plurality of interconnected FSC units). The top layer 121 and the bottom layer 122 are indicated as “thermoformable/thermoformed”, representing their state as “thermoformable” prior to the thermoforming process, and representing their state as “thermoformed” after the thermoforming process.

The thermoforming process may include, for example, providing a plastic sheet; heating the plastic sheet (e.g., using an oven, or using a heating device); using a mold to three-dimensionally shape or structure the heated plastic sheet to make it acquire a particular three-dimensional shape or structure (e.g., which corresponds to the three-dimensional shape or structure of the mold), or by using a mating mold and a pressure-box close together on the heated plastic sheet. Optionally, vacuum or suction units may be used in the thermoforming process to remove trapped air and/or to pull the heated plastic material into the mold; optionally, pressurized air may be used and/or plug-assists may be used, to facilitate the insertion or movement of the heated plastic sheet and/or to achieve a particular material distribution and thickness). Optionally, reverse air pressure may be used to enable air-based ejection of the thermoformed article; or other suitable ejection techniques may be used (e.g., using a stripper plate or ejector elements). Optionally, a trim station or a trim press unit may cut or trim the thermoformed article, or may produce a plurality of smaller discrete units from a larger thermoformed object.

The Applicants have realized that a material that may be suitable for the thermoformable/thermoformed layers (121 and/or 122) is polycarbonate, which is transparent or translucent, and is thermoformable, and can result in a thermoformed object that is sufficiently tough or sufficiently rigid or sufficiently firm (e.g., for utilization as a vehicular component). The Applicants have further realized that due to its toughness, thermoformed components made of polycarbonate can pass crash tests that are relevant to the automotive industry. Thermoformable polycarbonate sheets can be selected from a range of various thicknesses values (e.g., ranging from 2 to 15 millimeters) to accommodate a particular application. In some embodiments, clear or transparent or translucent polycarbonate sheets may be used. In some embodiments, Abrasion Resistant (AR) polycarbonate sheets may be used, and they may be clear or transparent or translucent.

The Applicants have also realized that other thermoformable polymers that may be suitable for thermoforming the top layer 121 and/or the bottom layer 122, instead of polycarbonate or in addition to it, are: acrylonitrile butadiene styrene (ABS), high impact polystyrene (HIPS), Polypropylene (PP), polyvinyl chloride (PVC), polyethylene terephthalate (PET), polyethylene terephthalate glycol (PETG), high density polyethylene (HDPE), or a combination of two or more of the above. In accordance with some embodiments, clear or partially-clear or mostly-clear thermoformable material(s) can be used; or transparent or partially-transparent or mostly-transparent thermoformable material(s) can be used; or translucent or partially-translucent or mostly-translucent thermoformable material(s) can be used.

In accordance with some embodiments, the production process may include producing a three-layer structure of: the thermoformable top layer plastic sheet, the thermoformable bottom layer plastic sheet, and the intermediate article 100 that is sandwiched between them; and then performing the thermoforming process on that three-layer structure, by utilizing thermoforming molds and tools that are configured or structured or shaped according to the shape or contour of a particular make-and-model of a vehicle; thereby producing a rigid or semi-rigid product in which a generally-flexible solar panel is embedded, wherein the internally-embedded generally-flexible solar panel is not the most outer layer of the vehicular component, but rather, the internally-embedded generally-flexible solar panel is embedded within at least a thermoformed layer (which is at least partially clear or transparent or translucent), and is optionally further protected by a topsheet and by a top-side encapsulant.

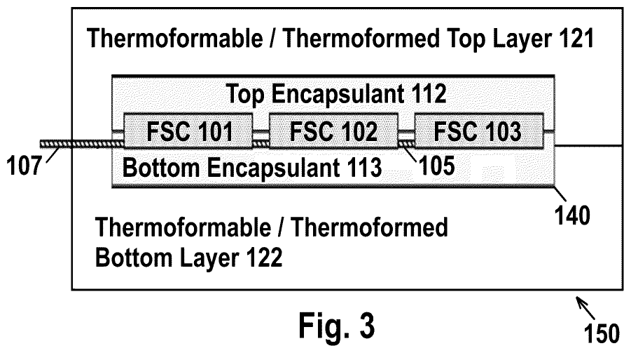

Reference is made to FIG. 3, which is a schematic illustration of a cross-sectional view (or a side-view) of a vehicular component 150 having embedded therein another type of intermediate article 140, in accordance with some demonstrative embodiments.

As demonstrated in FIG. 3, thermoformable sheets (e.g., polycarbonate, or other suitable thermoformable material(s) as discussed above) may be utilized to replace the topsheet and backsheet; such that the intermediate article 140 lacks or exclude a topsheet and a backsheet. The plurality of electrically-connected FSC units (101-103) are sandwiched between, and are encapsulated by, the top encapsulant 112 and the bottom encapsulant 113; thereby forming an intermediate article 140 that is topsheet-free and is backsheet-free, yet still has encapsulant layers (112 and 113) the protect and/or hold the FSC units (101-103). The intermediate article 140 is sandwiched between the thermoformable top layer 121 and the thermoformable bottom layer 122 (e.g., thermoformable polycarbonate sheets, or other thermoformable material(s) as discussed above). The laminated structure shown in FIG. 3 is ready to undergo the thermoforming process, which provides to the structure the desired three-dimensional shape that accommodates (or corresponds to) a particular vehicular component of a particular make-and-model of vehicle.

In some embodiments, optionally, the flexible solar cells (all of them, or most of them, or at least some of them) are not necessarily pre-encapsulated and/or pre-laminated; but rather, they may be introduced into the final product as an array of bare flexible solar cells that are electrically inter-connected to thus produce a PV module or sub-module that is capable of generating electricity, according to a pre-defined specification or arrangement or structure that corresponds to the structure of the relevant vehicular component. In some embodiments, optionally, a single vehicular component may incorporate or embed therein a combination of both (i) bare non-pre-encapsulated/non-pre-laminated flexible solar cells, and (ii) pre-encapsulated/pre-laminated flexible solar cells; for example, in order to provide a variety of solar cell types, as some types (e.g., pre-encapsulated/pre-laminated solar cells) may be more resilient to weather conditions or mechanical forces, whereas other types (e.g., not pre-encapsulated, not pre-laminated) may be less resilient yet may have a greater electricity-generation capability; and a mixture or combination of both types of flexible solar cell may be utilized to achieve a particular level of mechanical resilient as well as electricity-generation capability, per vehicular component or per vehicle.

In some embodiments, some or all of the flexible solar cells may be embedded within a vehicular component via a Resin Transfer Molding (RTM) process or other closed molding process, in which the flexible solar cell is embedded within a stack of layers that form the vehicular component via RTM. For example, a preform or fiber-based reinforcement (e.g., glass fiber, carbon fiber, aramid fiber, or the like) is created, and is provided into a mold cavity (e.g., between a female mold part and a male mold part) that has the shape of the desired vehicular component; the flexible solar cells are one of the layers that are inserted into the mold cavity; optionally, the internal sides of the mold cavity are gel-coated, to provide a high-quality finish; the mold cavity is closed and clamped (e.g., perimeter clamping, press clamping), the mold is heated, and a resin (e.g., a low-viscosity resin, Unsaturated Polyester Resin (UPR), epoxy, polyester, thermoplastic materials, or the like) is injected or pumped with pressure into the heated mold, while air exits from vent port(s), until the mold is filled; a curing cycle follows while the injected resin (and the flexible solar cells) are still within the mold, and the resin polymerizes to become rigid plastic that embed therein the generally-flexible solar cell. In some embodiments, flexible solar cells are embedded within layers of glass fibers and/or carbon fibers (and/or other fibers), and are inserted into the mold cavity to be part of the RTM-based fabrication of the vehicular component. In some embodiments, the resin is clear or at least partially (or mostly) transparent or translucent, to enable passage of at least some light towards the embedded solar cells. In some embodiments, optionally, injection molding may be performed in order to embed generally-flexible solar cells into a vehicular component that is being fabricated; for example, by placing or burying or inserting the generally-flexible solar cells as an insert during the injection molding process. In some embodiments, other suitable production methods may be used; particularly, processes that utilize thermoplastic or thermosetting polymers as a matrix material.

In some embodiments, the preparation of the stack of layers that include the flexible solar cell, may take into account the final desired shape or contour of the vehicular component and its intended or expected curvatures or curved regions or non-planar regions; such that, for example, one or more flexible solar cells may be positioned or placed at a particular location or position or angular position or slanting that enables increased reception of incoming right, and/or to increase the surface of flexible solar cell that are intended to efficiently receive incoming right for PV-generation of electricity.

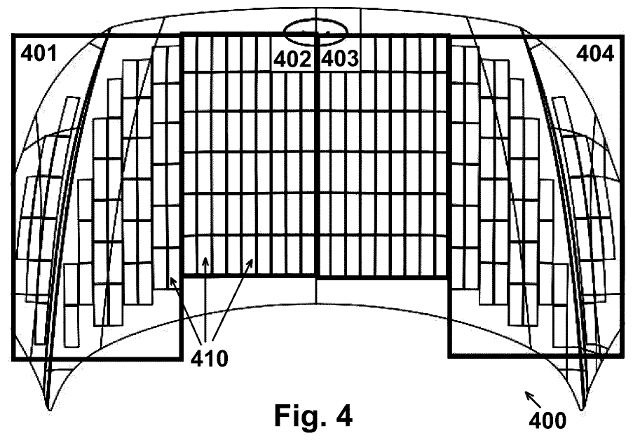

Reference is made to FIG. 4, which is a schematic illustration of an arrangement 400 of multiple, generally-flexible, solar cells 410 that are embedded within a vehicular hood or hood-cover, in accordance with some demonstrative embodiments. The arrangement 400 in this demonstrative example comprises four groups or strings 401-404 of solar cells that are connected in parallel, arranged longitudinally across the vehicular hood. In some embodiments, external or outer regions of the vehicular hood (e.g., regions of the vehicular hood that are closer to the outer edges of the vehicle itself) may include an increased number of flexible solar cells in order to compensate for possible losses of incoming light (that is converted to electricity) which may occur due to sharp inclinations and/or shadings.

In some embodiments, the flexible solar panels that are embedded within the vehicular component may be sandwiched by two plastic sheets (e.g. polycarbonate sheets) that are colored or tinted, for aesthetic purposes and/or to match the general color of the vehicle or the vehicular component; while such colored plastic sheets are still at least partially transparent and/or translucent to still enable passage of light therethrough. In some embodiments, the flexible solar panels that are embedded within the vehicular component may be sandwiched by one plastic sheets (e.g. polycarbonate sheet) that is colored or tinted, and another plastic sheet (e.g. polycarbonate sheet) that is not colored or not tinted. In some embodiments, one or more of the plastic sheets (e.g., polycarbonate sheet) may optionally include or have a design element or a functional element that provides a particular functionality; for example, a printed region, a logo, a slogan, a printed text, a texture, a color effect, a patterning effect (e.g., stripes, polygons), or the like; optionally being at least partially clear or transparent or translucent.

In some embodiments, the flexible solar cells and/or solar panels that are embedded within or into the vehicular component may optionally be sandwiched between layers of prepreg or pre-preg, or other composite material made from pre-impregnated fibers and a partially cured polymer matrix, and may be produced as a composite element or a composite material. The one or more layer(s) on the “sunny side” or the “active side” or the “sun-facing” side or the “light-facing side” of the solar cell(s) or panel(s) or element(s) are at least partially transparent and/or at least partially translucent, to enable passage therethrough of at least some (or most, or all) of the incoming light; and may be based upon (or may be formed of, or may include) glass fibers in a thermosetting matrix, such as epoxy, polyester, polyurethane, vinyl ester, and/or similar materials. The one or more layer(s) on the “back side” or the “dark side” or the “non-active side” of the solar cell(s) or panel(s) or element(s), or the side that is opposite to said “sunny side”, or the side that is not intended to directly receive incoming light, may optionally be transparent or translucent, or may be opaque or non-transparent or non-translucent, and need not necessarily enable passage of light therethrough; and may be based upon (or may be formed of, or may include) glass fibers, carbon fibers, basalt fibers, natural fibers, and/or a combinations thereof, in a thermosetting matrix such as epoxy, polyester, polyurethane, vinyl ester, and/or similar materials. The multilayered structure may be cured at ambient conditions, or may be cured in an oven or in a press, or by placement near or within a heating unit or in an autoclave at elevated temperatures and/or pressures. In some embodiments, the optional prepreg layer(s) may be curved or non-planar, or may have curved regions or curvatures or non-planar regions; which may correspond to, or may follow, similar curvature(s) of the relevant vehicular component.

In some embodiments, said optional prepreg layer(s) may be utilized instead of one or more of the following: the top-side encapsulant; the bottom-side encapsulant; the topsheet; the backsheet; the thermoformed top-layer; the thermoformed bottom-layer. In other embodiments, said optional prepreg layer(s) may be used instead of two or more of the following: following: the top-side encapsulant; the bottom-side encapsulant; the topsheet; the backsheet; the thermoformed top-layer; the thermoformed bottom-layer. In other embodiments, said optional prepreg layer(s) may be used as an additional layer which may directly touch, from above or from beneath, one of the following: the top-side encapsulant; the bottom-side encapsulant; the topsheet; the backsheet; the thermoformed top-layer; the thermoformed bottom-layer. In other embodiments, said optional prepreg layer(s) may be sandwiched as part of the stack-of-layers, beneath (or above) one of the following: the top-side encapsulant; the bottom-side encapsulant; the topsheet; the backsheet; the thermoformed top-layer; the thermoformed bottom-layer. In some embodiments, said optional prepreg layer(s) may be may be an additional layer, or may be several additional layers, of any other “sandwich” or stack of layers that is shown in any of the drawings and/or that is described above and/or herein.

In some embodiments, the flexible solar cells and/or solar panels that are embedded within (or into) the vehicular component may optionally be sandwiched between layers of fiber sheets and resins in a wet layup (or wet lay-up) process as a composite material or composite element. The one or more layer(s) on the “sunny side” or the “active side” or the “sun-facing” side or the “light-facing side” of the solar cell(s) or panel(s) or element(s) are at least partially transparent and/or at least partially translucent, to enable passage therethrough of at least some (or most, or all) of the incoming light; and may be based upon (or may be formed of, or may include) glass fibers in a thermosetting matrix such as epoxy, polyester, polyurethane, vinyl ester, and/or similar materials. The one or more layer(s) on the “back side” or the “dark side” or the “non-active side” of the solar cell(s) or panel(s) or element(s), or the side that is opposite to said “sunny side”, or the side that is not intended to directly receive incoming light, may optionally be transparent or translucent, or may be opaque or non-transparent or non-translucent, and need not necessarily enable passage of light therethrough; and may be based upon (or may be formed of, or may include) glass fibers, carbon fibers, basalt fibers, natural fibers, and/or a combinations thereof in a thermosetting matrix such as epoxy, polyester, polyurethane, vinyl ester, and/or similar materials. The multilayered structure may be cured at ambient conditions, or may be cured in an oven or in a press, or by placement near or within a heating unit or in an autoclave at elevated temperatures and/or pressures. In some embodiments, the optional layer(s) of fiber sheets and resins in a wet layup may be curved or non-planar, or may have curved regions or curvatures or non-planar regions; which may correspond to, or may follow, similar curvature(s) of the relevant vehicular component.

In some embodiments, said optional layer(s) of fiber sheets and resins in a wet layup may be utilized instead of one or more of the following: the top-side encapsulant; the bottom-side encapsulant; the topsheet; the backsheet; the thermoformed top-layer; the thermoformed bottom-layer. In other embodiments, said optional layer(s) of fiber sheets and resins in a wet layup may be used instead of two or more of the following: following: the top-side encapsulant; the bottom-side encapsulant; the topsheet; the backsheet; the thermoformed top-layer; the thermoformed bottom-layer. In other embodiments, said optional layer(s) of fiber sheets and resins in a wet layup may be used as an additional layer which may directly touch, from above or from beneath, one of the following: the top-side encapsulant; the bottom-side encapsulant; the topsheet; the backsheet; the thermoformed top-layer; the thermoformed bottom-layer. In other embodiments, said optional layer(s) of fiber sheets and resins in a wet layup may be sandwiched as part of the stack-of-layers, beneath (or above) one of the following: the top-side encapsulant; the bottom-side encapsulant; the topsheet; the backsheet; the thermoformed top-layer; the thermoformed bottom-layer. In some embodiments, said optional layer(s) of fiber sheets and resins in a wet layup may be an additional layer, or may be several additional layers, of any other “sandwich” or stack of layers that is shown in any of the drawings and/or that is described above and/or herein.

In some embodiments, and particularly when the vehicular component that embeds therein the solar cell is intended to be placed relative to other vehicular components (which may also have embedded solar cells, or which may lack any embedded solar cells), such vehicular component (e.g., a vehicular roof or roof cover, or vehicular trunk or trunk cover) may be structured or shaped to have a protruding edge or a curved edge or a particularly-shaped edge or bordering region, that corresponds to a gap that may occur between that vehicular component and the other vehicular component(s), such as between the vehicular roof and the vehicular doors (or windows, or facades), to ensure a snug fit of that vehicular component (that embeds therein the flexible solar cells) to the vehicle and its other/nearby vehicular components, and/or to facilitate the installation.

In some embodiments, the generally-flexible solar cells are embedded within a vehicular component that may have one or more functional coating layer(s), for example, anti-ultraviolet or anti-UV coating or UV-reducing coating or UV-filtering coating or UV-blocking coating, anti-scratch coating or scratch-resistant coating or scratch-reducing coating, anti-rust coating or rust-reducing coating, one or more coating layer(s) that increase mechanical durability and/or mechanical resilience and/or longevity, or the like. In some embodiments, optionally, the vehicular roof (or other vehicular component), that has flexible solar cells embedded therein, may be covered with a thermoplastic urethane (TPU) film or a Paint Protection Film (PPF); which may be applied before and/or the installation of the vehicular roof (or other vehicular component) and/or before its attachment to one or more other vehicular components.

In some embodiments, the vehicular component that has the generally-flexible solar cells embedded therein, may be an integrated vehicular component or a singular vehicular component, such as, an entire vehicular roof or an entire vehicular hood or an entire vehicular trunk-cover or an entire vehicular side-panel or door. In other embodiments, the vehicular component that has the generally-flexible solar cells embedded therein, may be fabricated as a separate or an add-on component or cover or covering layer or covering component, that is then attached (or, is non-removably attached; or non-detachably attached) to a corresponding vehicular component, on or onto the external side of such corresponding vehicular component (e.g., the side the is facing outwardly or away from the vehicle, and not the side that is facing inwardly or internally towards the interior of the vehicle). The attachment may be performed via one or more mechanical connection means or attachments means; for example, screws, nails, male-female connectors, double-sided adhesive tape strips or tape sheets or adhesive tapes or adhesive sheets, glue, adhesive, bonding agent, or other type of permanent or non-reversible or non-detachable attachment mechanism, or other type of temporary or reversible or detachable mechanism.

In some embodiments, similar to embedding flexible solar cells via thermoforming into a vehicular roof or a vehicular component, flexible solar cells may be similarly embedded via thermoforming into other articles; for example, a roof of a bus-stop or a train station or a gas station, a roof of a gazebo or balcony or porch, a greenhouse, a roof of a shack or shed or toolshed or storage shed or storage shack, a roof or a top-side cover or a parking spot or a parking lot or a parking infrastructure, a roof of an electric charging stations for vehicles, a roof or cover of a playground or a stadium or a sporting venue, a roof or cover of an agricultural machinery or construction machinery (e.g., tractor, bulldozer, excavator, cement truck, crane, garbage collection truck, cargo truck), a shipping container, a storage pod, or the like. In some embodiments, such embedded solar cells may provide PV-generated electricity that may be utilized for a variety of goals; for example, to provide PV-generated electricity to a cooling system that in turn reduces the temperature within such article (e.g., top-layer shipping containers on a cargo ship) or within such venue (e.g., cooling of a roofed yard or backyard or playground or tennis court or sporting venue); to provide PV-generated electricity for charging or recharging a vehicle or electrical equipment or electrical appliances; or for other electricity storage devices or electricity consuming devices.

In accordance with some embodiments, the flexible or generally-flexible solar cells or solar panels, are flexible and/or generally-flexible at least prior to their embedded into the vehicular component (or other article). In some embodiments, such flexible or generally-flexible solar cells maintain at least some (but not necessarily all) of their flexing capability or their curving capability or their mechanical resilience properties, upon and/or after their embedding into the vehicular component (or other article); even if the immediately surrounding of the embedded solar cells may be rigid, or may partially limit or constrain the ability of such embedded solar panels to fully flex or to fully curve in response to mechanical forces; and such embedded flexible or generally-flexible solar cells may maintain at least some of their curving capability or flexing capability, or their capability to remain functional or mostly functional even after their embedding into such generally-rigid surrounding article or vehicular component. It is noted that in some embodiments, for example, the vehicular component that surrounds the embedded flexible or generally-flexible solar cells, may have some level of curving/flexing capability of its own; such as, if such vehicular component is formed of steel or other metal. In some embodiments, the flexible or generally-flexible solar cells may exhibit less sensitivity to (or, increased resilience to) vibrations and/or mechanical forces and/or mechanical other stresses that may be applied on the vehicular component (or other article), in comparison to a conventional, non-flexible, glass-covered, fragile or brittle solar panel.

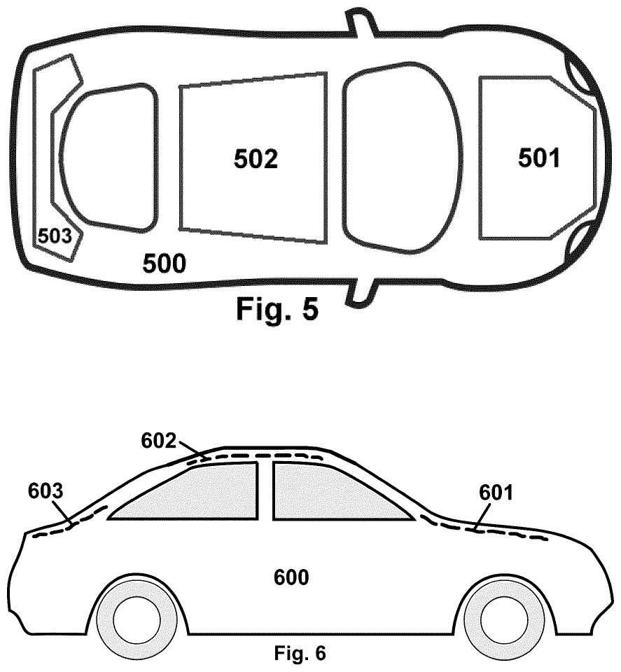

Reference is made to FIG. 5, which is a schematic illustration of a top-view of a vehicle 500, having vehicular components with embedded generally-flexible solar cells, in accordance with some demonstrative embodiments. For example, the hood of vehicle 500 has a polygon-shaped region 501 which has embedded therein a plurality of inter-connected generally-flexible solar cells; the roof of vehicle 500 has a trapezoid-shaped region 502 which has embedded therein another plurality of inter-connected generally-flexible solar cells; the trunk cover of vehicle 500 has another polygon-shaped region 503 which has embedded therein another plurality of inter-connected generally-flexible solar cells. The generally-flexible solar cells that are embedded in the vehicular components, generate electricity from light via the PV effect, and provide the PV-generated electricity to the battery or batteries or power cell(s) of the vehicle itself, and/or to the electrical system of the vehicle itself (e.g., for storage and/or for immediate consumption), and/or to batteries or power cells of devices within the vehicle (e.g., to provide PV-generated electricity to a smartphone or a tablet or a laptop that is located within the vehicle and that received electricity via a cable from an electric socket within the vehicle). Each one of the regions (501, 502, 503) may have other structure or shapes; and the top-view as depicted in FIG. 5 is a two-dimensional representation while the actual arrangement of embedded flexible solar cells may be non-planar or non-flat or may have curvatures or curved regions that correspond to the curved or non-planar contour of the vehicle.

Reference is made to FIG. 6, which is a schematic illustration of a cross-section view of a vehicle 600, having vehicular components with embedded generally-flexible solar cells, in accordance with some demonstrative embodiments. For example, a vehicular hood has a first set 601 of Flexible Solar Cell (FSC) units embedded therein; a vehicular roof has a second set 602 of FSC units embedded therein; a vehicular trunk cover has a third set 603 of FSC units embedded therein. For demonstrative purposes, the FSC units are shown oversized; whereas in some embodiments the thickness of each FSC can be (for example) in the range of 0.1 to 10 millimeters, or other suitable thickness values. For demonstrative purposes, the FSC are shown as discrete units, which they indeed are; yet they are typically interconnected electrically and/or mechanically. For demonstrative purposes, some of the FSC units are shown as being planar or linear, whereas some other of the FSC units are intentionally shown as being curved or having one or more curvatures, to demonstrate that the FSC units may indeed have such non-planar shape or non-linear cross section, to conform to (or to follow, or to match) the three-dimensional contour of the relevant vehicular part or vehicular region.

Some embodiments may provide the following features: (1) Flexible solar cell(s) that are integrally embedded within a part of a vehicle; (2) A method of embedding a singulated or trenched or grooved or otherwise flexible solar cell or solar panel within a vehicle part; (3) a method of embedding flexible and/or singulated solar cells within a vehicle part; (4) Generally-flexible solar cells that are incorporated or embedded within a firm object or a rigid article, wherein such object or article has curvature and/or non-planar regions, and/or can be prone to small movements due to mechanical forces.

### Additional/Optional Features

In some embodiments, a solar cell that is utilized in conjunction with the Joining Unit, may be an autonomously flexible and/or rollable and/of foldable solar cell, that does not break and does not brittle when flexed or curved or bent or folded or rolled, and that is resilient to mechanical forces, and that can autonomously absorb and/or dissipate and/or withstand mechanical forces and mechanical shocks; for example, by being segmented or grooved or trenched with non-transcending gaps or “blind gaps” or craters or grooves or trenches, that penetrate some—but not all—of the thickness (or the depth) of a silicon layer or a semiconductor body or a semiconductor wafer; and optionally by having filler material(s) in such grooves or trenches or non-transcending gaps or non-transcending craters, to further absorb and/or dissipate mechanical forces and shocks.

Optionally, some embodiments may be utilized in conjunction with PV devices and/or solar panels and/or components and/or methods that are described in patent number U.S. Pat. No. 11,081,606, titled “Flexible and rollable photovoltaic cell having enhanced properties of mechanical impact absorption”, which is hereby incorporated by reference in its entirety; and/or in conjunction with components, structures, devices, methods, systems and/or techniques that are described in patent application number U.S. Ser. No. 17/353,867, filed on Jun. 22, 2021, published as US 2021/0313478, which is hereby incorporated by reference in its entirety; and/or with solar panels or solar cells or PV devices that are singulated or segmented or trenched or grooved, or that are flexible and/or rollable and/or foldable, and/or that include “blind gaps” or non-transcending gaps or craters. Some embodiments may provide a flexible and rollable PV cell or solar cell; wherein a silicon body or semiconductor body or semiconductor substrate or semiconductor wafer has non-transcending craters or “blind gaps” that penetrate into between 75 percent and 99 percent of a total thickness of the semiconductor body (or wafer, or substrate), and that do not penetrate into an entirety of the total thickness of the semiconductor body (or wafer, or substrate); wherein said non-transcending craters or “blind gaps” increase flexibility/or and mechanical resilience and/or mechanical shock absorption of the PV cell. In some embodiments, some, or most, or all of the non-transcending craters or “blind gaps” contain a filler material having mechanical force absorption properties, which provides mechanical shock absorption properties and/or mechanical force dissipation properties to the PV cell.

In some embodiments, each of the solar cells is rollable and flexible by itself; and is a single PV device or is a single PV article, that is comprised of a single semiconductor substrate or a single semiconductor wafer or a single semiconductor body; which is monolithic, e.g., is currently, and has been, a single item or a single article or a single component that was formed as (and remained) a single component; such that each solar cell is not formed as a collection or two or more separate units or as a collection of two or more entirely-separated or entirely-discrete or entirely-gapped units that were arranged or placed together in proximity to each other yet onto a metal foil or onto a metal film or onto a flexible or elastic foil or film.

In some embodiments, each single solar cell that is flexible and rollable by itself, is not a collection and is not an arrangement and is not an assembly of multiple discrete solar cells of PV modules, that each one of them has its own discrete and fully separated semiconductor substrate and/or its own discrete and fully separated semiconductor wafer and/or its own discrete and fully separated semiconductor body, and that have been merely placed to assembled or arranged together (or mounted together, or connected together) onto or beneath a flexible foil or a flexible film; but rather, the each single solar cell has a single unified semiconductor substrate or semiconductor body or semiconductor wafer that is common to, and is shared by, all the sub-regions or areas or portions of that single solar cell which includes therein (in that unified single semiconductor substrate or wafer or body) those non-transcending craters or non-transcending gaps or “blind gaps” that penetrate only from one side (and not from both sides), which do not reach all the way through and do not reach all the way to the other side of the unified single semiconductor substrate or wafer or body.

In some embodiments, each solar cell may be, or may include, a mono-crystalline PV cell or solar panel or solar cell, a poly-crystalline PV cell or solar panel or solar cell, a flexible PV cell or solar cell that is an Interdigitated Back Contact (IBC) solar cell having said semiconductor wafer with said set of non-transcending gaps, and/or other suitable type of PV cell or solar cell.

Some portions of the discussion above and/or herein may relate to regions or segments or areas, of the semiconductor body or substrate or wafer (or PV cell, or PV device); yet those “segments” are still touching each other and/or inherently connected to each other and/or non-separated from each other, as those “segments” are still connected by at least a thin portion or a thin bottom-side surface of the semiconductor substrate (or wafer, or body), which still holds and includes at least 1 (or at least 2, or at least 3, or at least 5, or at least 10, or at least 15, or at least 20, or at least 25, or at least 33; but not more than 50, or not more than 40) percent of the entire depth or the entire thickness (or the maximum thickness or depth) of the semiconductor substrate or body or wafer; as those “segments” are still connected at their base through such thin layer, and those “segments” have between them (or among them) the non-transcending gaps or the “blind gaps” or the non-transcending craters that thus separate those “segments” but that do not fully divide or fully break or fully isolate any two such neighboring “segments” from each other. Upon its production, and prior to attaching the solar cells onto the floating medium layer, each such flexible and rollable solar cell is freestanding and carrier-less and non-supported.

In some embodiments, the non-transcending gaps or the “blind gaps” or craters or slits or grooves, are introduced and are formed only at a first side or at a first surface of the semiconductor substrate or body or wafer, and are not formed at both of the opposite surfaces (or sides) thereof.

In some embodiments, the non-transcending gaps or the “blind gaps” or craters or slits or grooves, are introduced and are formed only at a first side or at a first surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; and they are not formed at the other (e.g., opposite, non-active) side or surface (e.g., the side that is not intended to be facing the sunlight or the light, or the side that is not intended to be producing electricity based on the PV effect).

In other embodiments, the non-transcending gaps or the “blind gaps” or craters or slits or grooves, are not introduced and are not formed at the side or surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; but rather, those non-transcending gaps or the “blind gaps” or craters or slits or grooves are formed at the other (e.g., opposite, non-active) side or surface, which is the side that is not intended to be facing the sunlight or the light, or the side that is not intended to be producing electricity based on the PV effect. Some implementations with this structure may advantageously provide the mechanical shock absorption and the mechanical forces dissipation capability, yet may also provide or maintain or achieve an increased level of PV-based electricity production since the gaps do not reduce the area of the light-exposed side or the light-facing side of the PV device.

In still other embodiments, the non-transcending gaps or the “blind gaps” or craters or slits or grooves, are introduced and are formed at both sides or at both surfaces of the semiconductor substrate or body or wafer; yet with an offset among the gaps of the first side and the gaps of the second side, in a zig-zag pattern of those gaps which zig-zag across the two sides of the semiconductor wafer or substrate or body; for example, a first gap located at the top surface on the left; then, a second gap located at the bottom surface to the right side of the first gap and not overlapping at all with the first gap; then, a third gap located at the top surface to the right side of the second gap and not overlapping at all with the second gap; then, a fourth gap located at the bottom surface to the right side of the third gap and not overlapping at all with the third gap; and so forth. In such structure, for example, any single point or any single location or any single region of the remaining semiconductor wafer or substrate or wafer, may have a gap or a crater or a “blind gap” only on one of its two sides, but not on both of its sides.

In yet other embodiments, the non-transcending gaps or the “blind gaps” or craters or slits or grooves, are introduced and are formed at both sides or at both surfaces of the semiconductor substrate or body or wafer; not necessarily with an offset among the gaps of the first side and the gaps of the second side, and not necessarily in a zig-zag pattern; but rather, by implementing any other suitable structure or pattern that still provides the mechanical shock resilience, and while also maintaining a sufficiently-thin layer of semiconductor substrate or body or wafer that is not removed and that is resilient to mechanical shocks and mechanical forces due to the craters or gaps that surround it.

Some embodiments may include and/or may utilize one or more units, devices, connectors, wires, electrodes, and/or methods which are described in United States patent application publication number US 2016/0308155 A1, which is hereby incorporated by reference in its entirety. For example, some embodiments may include and may utilize an electrode arrangement which is configured to define or create a plurality of electricity collection regions, such that within each of the collection regions, at least two sets of conducting wires are provided such that they are insulated from each other, and the at least two sets of conducting wires are connected either in parallel or in series between the collection regions to thus provide accumulating voltage of charge collection. Some embodiments may include an electric circuit for reading-out or collection or aggregation of the generated electricity, configured as an electrode arrangement, including conducting wires arranged in the form of nets covering zones of a pre-determined area. The electrodes arrangement may be configured or structured to be stretched (e.g., rolled out) along the surface of the PV cell, and may be formed by at least two sets of conducting wires, and may cover a plurality of collection zones or collection regions.

Within each of the electricity collection zones or electricity aggregation zones, the different conducting wires are insulated from each other, to provide a certain voltage between them. At a transition between zones, the negative charges collecting conductive wire of one zone, is electrically connected to the positive charges collecting conductive wire of the adjacent or the consecutive zone. Thus, within each of the collection zones, the different sets of conducting wires are insulated from each other, while being connected in series between the zones. This configuration of the electrode arrangement allows accumulation or aggregation of electric voltage generated by charge collection along the surface of the PV device. The configuration of the electrode arrangement provides a robust electric collection structure.

The internal connections between the sets of conducting wires allow energy collection even if the surface being covered is not continuous, e.g., if a perforation occurs in the structure of the net. This feature of the electrode arrangement allows for using this technique on any surface exposed to photon radiation, while also allowing discontinuity if needed and without limiting or disrupting the electric charge collection.

Some embodiments provide an article comprising: a vehicular component, that is configured to be a part of a vehicle. The vehicular component has an outwardly-facing non-planar surface, which has embedded therein a plurality of electrically inter-connected generally-flexible solar cells. The electrically inter-connected generally-flexible solar cells that are embedded within said vehicular component, generate electricity from light and provide electricity to at least one of: (i) said vehicle, (ii) a battery of said vehicle, (iii) an electric device within said vehicle. In some embodiments, the generally-flexible solar cells are embedded within the outwardly-facing non-planar surface of said vehicular component, and they are not directly touching the air that surrounds said vehicle.

In some embodiments, the generally-flexible solar cells are embedded within the outwardly-facing non-planar surface of said vehicular component, and they are not directly touching the air that surrounds said vehicle, and they are sandwiched between a top-side encapsulant and a bottom-side encapsulant that hold and mechanically protect said generally-flexible solar cells. At least the top-side encapsulant is at least mostly transparent or at least mostly translucent to light, and enables passage of incoming light from an external surrounding of the vehicle towards an active surface of the generally-flexible solar cells.

In some embodiments, a stack of (I) said top-side encapsulant and (II) said generally-flexible solar cells and (III) said bottom-side encapsulant, is further sandwiched between a topsheet and a backsheet that hold and mechanically protect said stack. At least the topsheet is at least mostly transparent or at least mostly translucent to light, and enables passage of incoming light from the external surrounding of the vehicle towards the active surface of the generally-flexible solar cells.

In some embodiments, a stacked set of (I) said topsheet and (II) said top-side encapsulant and (III) said generally-flexible solar cells and (IV) said bottom-side encapsulant and (V) said backsheet, is further sandwiched between a thermoformed top-layer and a thermoformed bottom-layer. At least the thermoformed top-layer is at least mostly transparent or at least mostly translucent to light, and enables passage of incoming light from the external surrounding of the vehicle towards the active surface of the generally-flexible solar cells.

In some embodiments, a stacked set of (I) said top-side encapsulant and (III) said generally-flexible solar cells and (III) said bottom-side encapsulant, is further sandwiched between a thermoformed top-layer and a thermoformed bottom-layer. At least the thermoformed top-layer is at least mostly transparent or at least mostly translucent to light, and enables passage of incoming light from the external surrounding of the vehicle towards the active surface of the generally-flexible solar cells. Said stacked set excludes a topsheet and excludes a backsheet; and said thermoformed top-layer and said thermoformed bottom-layer hold and mechanically protect said generally-flexible solar cells.

In some embodiments, at least said thermoformed top-layer is formed of polycarbonate.

In some embodiments, at least said thermoformed top-layer is formed of one or more materials selected from the group consisting of: acrylonitrile butadiene styrene (ABS), high impact polystyrene (HIPS), Polypropylene (PP), polyvinyl chloride (PVC), polyethylene terephthalate (PET), polyethylene terephthalate glycol (PETG), high density polyethylene (HDPE).

In some embodiments, at least one of said generally-flexible solar cells is flexible and rollable and is non-brittle prior to its embedding into said vehicular component, and maintains most of its capability to convert light into electricity even upon flexing or rolling of its structure.

In some embodiments, the at least one of said generally-flexible solar cells, continues to have at least some flexing and curving capability and continues to remain functional and non-brittle, upon and subsequent to its embedding into said vehicular component.

In some embodiments, the at least one of said generally-flexible solar cells, comprises a semiconductor wafer that is trenched or grooved by non-transcending craters, that penetrate into between 51 to 99 percent of an entire thickness of said semiconductor wafer; wherein said non-transcending craters provide mechanical resilience and flexing capability to said solar cell, and absorb and dissipate mechanical forces that are applied to said solar cell. In some embodiments, said non-transcending craters are filled, at least partially, with a filler material; wherein said filler material further absorbs and dissipates mechanical forces that are applied to said solar cell; wherein said filler material provides further mechanical resilience and flexing capability to said solar cell.

In some embodiments, said generally-flexible solar cells are arranged in a non-planar three-dimensional arrangement, that matches and follows a three-dimensional contour of said vehicular component; wherein said non-planar three-dimensional arrangement of said generally-flexible solar cells, that are embedded within said vehicular component, is configured to increase or optimize exposure of said generally-flexible solar cells to incoming light.

In some embodiments, the generally-flexible solar cells are embedded within a thermoformed sandwich of two thermoformed layers, of said vehicular component.

In some embodiments, the generally-flexible solar cells are embedded within a molded sandwich of two molded layers of said vehicular component, wherein each of said two molded layers is a Resin Transfer Molded layer; wherein the generally-flexible solar cells are solar cells that have underwent insertion into a heated mold cavity of a Resin Transfer Molding machine.

In some embodiments, the generally-flexible solar cells are embedded within a molded sandwich of two molded layers of said vehicular component, wherein each of said two molded layers is an Injection Molded layer; wherein the generally-flexible solar cells are solar cells that have underwent insertion into a heated mold cavity of an Injection Molding machine.

In some embodiments, the generally-flexible solar cells are embedded within the outwardly-facing non-planar surface of said vehicular component which comprises: at least one prepreg layer made from pre-impregnated fibers and a partially cured polymer matrix.

In some embodiments, the generally-flexible solar cells are embedded within the outwardly-facing non-planar surface of said vehicular component which comprises: at least one layer of a composite material of fiber sheets and resins formed in a wet layup process.

In some embodiments, said generally-flexible solar cells are integrally, permanently, non-removably and non-detachably embedded within said vehicular component.

In some embodiments, the vehicular component is a component selected from the group consisting of: a non-planar vehicular roof, a non-planar vehicular hood cover, a non-planar vehicular trunk cover, a non-planar vehicular door, a non-planar vehicular side-panel.

In some embodiments, said article is said vehicle which comprises said vehicular component.

Some embodiments provide a method of manufacturing a vehicular component, the method comprising: producing a plurality of generally-flexible solar cells, that are flexible and rollable and non-brittle, and that remain functional even upon flexing or curving or rolling; electrically inter-connecting the plurality of generally-flexible solar cells; three-dimensionally structuring the plurality of generally-flexible solar cells, in accordance with a pre-defined three-dimensional structure that matches and follows a three-dimensional contour of said vehicular component; non-detachably embedding the plurality of generally-flexible solar cells into an outwardly-facing non-planar surface of said vehicular component; providing electrical connectors that transfer photovoltaic-generated electricity, from said plurality of generally-flexible solar cells that are embedded within said vehicular component, to an electricity-storing device or an electricity-consuming device of a vehicle that includes said vehicular component.

In some embodiments, the embedding comprises: performing a thermoforming process that produces a stacked sandwich of at least: (i) a top-side thermoformed layer, and (ii) said generally-flexible solar cells, and (iii) a bottom-side thermoformed layer.

In some embodiments, the embedding comprises: producing said stacked sandwich that further includes at least one of: a top-side encapsulant that is sandwiched between (I) a top-side of the generally-flexible solar cells and (II) said top-side thermoformed layer; a bottom-side encapsulant that is sandwiched between (I) a bottom-side of the generally-flexible solar cells and (II) said bottom-side thermoformed layer;

In some embodiments, the embedding comprises: producing said stacked sandwich that further includes at least one of: a top-side encapsulant that is sandwiched between (I) a top-side of the generally-flexible solar cells and (II) a topsheet that is located beneath said top-side thermoformed layer; a bottom-side encapsulant that is sandwiched between (I) a bottom-side of the generally-flexible solar cells and (II) a backsheet that is located over said bottom-side thermoformed layer.

The terms “plurality” and “a plurality”, as used herein, include, for example, “multiple” or “two or more”. For example, “a plurality of items” includes two or more items.

References to “one embodiment”, “an embodiment”, “demonstrative embodiment”, “various embodiments”, “some embodiments”, and/or similar terms, may indicate that the embodiment(s) so described may optionally include a particular feature, structure, or characteristic, but not every embodiment necessarily includes the particular feature, structure, or characteristic. Furthermore, repeated use of the phrase “in one embodiment” does not necessarily refer to the same embodiment, although it may. Similarly, repeated use of the phrase “in some embodiments” does not necessarily refer to the same set or group of embodiments, although it may.

As used herein, and unless otherwise specified, the utilization of ordinal adjectives such as “first”, “second”, “third”, “fourth”, and so forth, to describe an item or an object, merely indicates that different instances of such like items or objects are being referred to; and does not intend to imply as if the items or objects so described must be in a particular given sequence, either temporally, spatially, in ranking, or in any other ordering manner.

Functions, operations, components and/or features described herein with reference to one or more embodiments, may be combined with, or may be utilized in combination with, one or more other functions, operations, components and/or features described herein with reference to one or more other embodiments. Some embodiments may thus comprise any possible or suitable combinations, re-arrangements, assembly, re-assembly, or other utilization of some or all of the modules or functions or components that are described herein, even if they are discussed in different locations or different chapters of the above discussion, or even if they are shown across different drawings or multiple drawings.

While certain features of some demonstrative embodiments have been illustrated and described herein, various modifications, substitutions, changes, and equivalents may occur to those skilled in the art. Accordingly, the claims are intended to cover all such modifications, substitutions, changes, and equivalents.

What is claimed is:

1. An article comprising:
a vehicular component, that is configured to be a part of a vehicle;
wherein the vehicular component has an outwardly-facing non-planar surface, which has embedded therein a plurality of electrically inter-connected generally-flexible solar cells;
wherein the electrically inter-connected generally-flexible solar cells that are embedded within said vehicular component, generate electricity from light and provide electricity to at least one of: (i) said vehicle, (ii) a battery of said vehicle, (iii) an electric device within said vehicle.

2. The article of claim 1,
wherein the generally-flexible solar cells are embedded within the outwardly-facing non-planar surface of said vehicular component, and they are not directly touching the air that surrounds said vehicle.

3. The article of claim 1,
wherein the generally-flexible solar cells are embedded within the outwardly-facing non-planar surface of said vehicular component, and they are not directly touching the air that surrounds said vehicle, and they are sandwiched between a top-side encapsulant and a bottom-side encapsulant that hold and mechanically protect said generally-flexible solar cells;
wherein at least the top-side encapsulant is at least mostly transparent or at least mostly translucent to light, and enables passage of incoming light from an external surrounding of the vehicle towards an active surface of the generally-flexible solar cells.

4. The article of claim 3,
wherein a stack of (I) said top-side encapsulant and (II) said generally-flexible solar cells and (III) said bottom-side encapsulant, is further sandwiched between a topsheet and a backsheet that hold and mechanically protect said stack;
wherein at least the topsheet is at least mostly transparent or at least mostly translucent to light, and enables passage of incoming light from the external surrounding of the vehicle towards the active surface of the generally-flexible solar cells.

5. The article of claim 4,
wherein a stacked set of (I) said topsheet and (II) said top-side encapsulant and (III) said generally-flexible solar cells and (IV) said bottom-side encapsulant and (V) said backsheet, is further sandwiched between a thermoformed top-layer and a thermoformed bottom-layer;
wherein at least the thermoformed top-layer is at least mostly transparent or at least mostly translucent to light, and enables passage of incoming light from the external surrounding of the vehicle towards the active surface of the generally-flexible solar cells.

6. The article of claim 4,
wherein a stacked set of (I) said top-side encapsulant and (III) said generally-flexible solar cells and (III) said bottom-side encapsulant, is further sandwiched between a thermoformed top-layer and a thermoformed bottom-layer;
wherein at least the thermoformed top-layer is at least mostly transparent or at least mostly translucent to light, and enables passage of incoming light from the external surrounding of the vehicle towards the active surface of the generally-flexible solar cells;
wherein said stacked set excludes a topsheet and excludes a backsheet, and wherein said thermoformed top-layer and said thermoformed bottom-layer hold and mechanically protect said generally-flexible solar cells.

7. The article of claim 4,
wherein at least said thermoformed top-layer is formed of polycarbonate.

8. The article of claim 4,
wherein at least said thermoformed top-layer is formed of one or more materials selected from the group consisting of:
acrylonitrile butadiene styrene (ABS),
high impact polystyrene (HIPS),
Polypropylene (PP),
polyvinyl chloride (PVC),
polyethylene terephthalate (PET),
polyethylene terephthalate glycol (PETG),
high density polyethylene (HDPE).

9. The article of claim 1,
wherein at least one of said generally-flexible solar cells is flexible and rollable and is non-brittle prior to its embedding into said vehicular component, and maintains most of its capability to convert light into electricity even upon flexing or rolling of its structure.

10. The article of claim 9,
wherein the at least one of said generally-flexible solar cells, continues to have at least some flexing and curving capability and continues to remain functional and non-brittle, upon and subsequent to its embedding into said vehicular component.

11. The article of claim 10,
wherein the at least one of said generally-flexible solar cells, comprises a semiconductor wafer that is trenched or grooved by non-transcending craters, that penetrate into between 51 to 99 percent of an entire thickness of said semiconductor wafer; wherein said non-transcending craters provide mechanical resilience and flexing capability to said solar cell, and absorb and dissipate mechanical forces that are applied to said solar cell.

12. The article of claim 11,
wherein said non-transcending craters are filled, at least partially, with a filler material; wherein said filler material further absorbs and dissipates mechanical forces that are applied to said solar cell; wherein said filler material provides further mechanical resilience and flexing capability to said solar cell.

13. The article of claim 12,
wherein said generally-flexible solar cells are arranged in a non-planar three-dimensional arrangement, that matches and follows a three-dimensional contour of said vehicular component;
wherein said non-planar three-dimensional arrangement of said generally-flexible solar cells, that are embedded within said vehicular component, is configured to increase or optimize exposure of said generally-flexible solar cells to incoming light.

14. The article of claim 12,
wherein the generally-flexible solar cells are embedded within a thermoformed sandwich of two thermoformed layers, of said vehicular component.

15. The article of claim 12,
wherein the generally-flexible solar cells are embedded within a molded sandwich of two molded layers of said vehicular component, wherein each of said two molded layers is a Resin Transfer Molded layer; wherein the generally-flexible solar cells are solar cells that have underwent insertion into a heated mold cavity of a Resin Transfer Molding machine.

16. The article of claim 12,
wherein the generally-flexible solar cells are embedded within a molded sandwich of two molded layers of said vehicular component, wherein each of said two molded layers is an Injection Molded layer; wherein the generally-flexible solar cells are solar cells that have underwent insertion into a heated mold cavity of an Injection Molding machine.

17. The article of claim 12,
wherein the generally-flexible solar cells are embedded within the outwardly-facing non-planar surface of said vehicular component which comprises: at least one prepreg layer made from pre-impregnated fibers and a partially cured polymer matrix.

18. The article of claim 12,
wherein the generally-flexible solar cells are embedded within the outwardly-facing non-planar surface of said vehicular component which comprises: at least one layer of a composite material of fiber sheets and resins formed in a wet layup process.

19. The article of claim 12,
wherein said generally-flexible solar cells are integrally, permanently, non-removably and non-detachably embedded within said vehicular component.

20. The article of claim 1,
wherein the vehicular component is a component selected from the group consisting of:
a non-planar vehicular roof,
a non-planar vehicular hood cover,
a non-planar vehicular trunk cover,
a non-planar vehicular door,
a non-planar vehicular side-panel.

21. The article of claim 1,
wherein said article is said vehicle which comprises said vehicular component.

22. A method of manufacturing a vehicular component, the method comprising:
producing a plurality of generally-flexible solar cells, that are flexible and rollable and non-brittle, and that remain functional even upon flexing or curving or rolling;
electrically inter-connecting the plurality of generally-flexible solar cells;
three-dimensionally structuring the plurality of generally-flexible solar cells, in accordance with a pre-defined three-dimensional structure that matches and follows a three-dimensional contour of said vehicular component;
non-detachably embedding the plurality of generally-flexible solar cells into an outwardly-facing non-planar surface of said vehicular component;
providing electrical connectors that transfer photovoltaic-generated electricity, from said plurality of generally-flexible solar cells that are embedded within said vehicular component, to an electricity-storing device or an electricity-consuming device of a vehicle that includes said vehicular component.

23. The method of claim 22,
wherein the embedding comprises:
performing a thermoforming process that produces a stacked sandwich of at least: (i) a top-side thermoformed layer, and (ii) said generally-flexible solar cells, and (iii) a bottom-side thermoformed layer.

24. The method of claim 23,
wherein the embedding comprises:
producing said stacked sandwich that further includes at least one of:
a top-side encapsulant that is sandwiched between (I) a top-side of the generally-flexible solar cells and (II) said top-side thermoformed layer;
a bottom-side encapsulant that is sandwiched between (I) a bottom-side of the generally-flexible solar cells and (II) said bottom-side thermoformed layer.

25. The method of claim 23,
wherein the embedding comprises:
producing said stacked sandwich that further includes at least one of:
a top-side encapsulant that is sandwiched between (I) a top-side of the generally-flexible solar cells and (II) a topsheet that is located beneath said top-side thermoformed layer;
a bottom-side encapsulant that is sandwiched between (I) a bottom-side of the generally-flexible solar cells and (II) a backsheet that is located over said bottom-side thermoformed layer.
